(19) United States
(12) Patent Application Publication
(10) Pub. No.: US 2011/0205704 A1
(43) Pub. Date: Aug. 25, 2011

(54) ELECTRONIC APPARATUS

(75) Inventor: Jun OSHIMA, Kawasaki (JP)

(73) Assignee: FUJITSU LIMITED, Kawasaki-shi (JP)

(21) Appl. No.: 13/018,820

(22) Filed: Feb. 1, 2011

(30) Foreign Application Priority Data
Feb. 19, 2010 (JP) 2010-34369

(51) Int. Cl. H05K 7/20

(52) U.S. Cl. 361/695

(57) ABSTRACT

An electronic apparatus includes a main unit having a front face and a rear face and housing an electronic component; a support base; and a post provided upright on the support base and connected to the rear face of the main unit while supporting the main unit in such an orientation that the front face of the main unit extends upright, the post including a fan producing a flow of air passing through an inside of the main unit.

### CROSS-REFERENCE TO RELATED APPLICATIONS

This application is based upon and claims the benefit of priority from the prior Japanese Patent Application No. 2010-34369 filed on Feb. 19, 2010, the entire contents of which are incorporated herein by reference.

### FIELD

The present embodiment relates to an electronic apparatus including a fan.

### BACKGROUND

Some electronic apparatuses, such as personal computers, include thereinside electronic components that generate heat when in operation. In general, such electronic apparatuses also include fans that cool the insides thereof. In response to demands for smaller and thinner apparatuses, a number of electronic components are closely arranged in the electronic apparatuses. Accordingly, cooling fans in the electronic apparatuses are provided close to or partially overlap some electronic components. Therefore, it is difficult to provide large fans in such electronic apparatuses, and most electronic apparatuses include small fans. In a case where a small fan is provided in an electronic apparatus, some measures for providing a sufficient volume of airflow are taken in which, for example, the fan is operated at a high speed and/or a plurality of small fans are interspersed in the apparatus. If the fan is operated at a high speed, however, a problem of loud noise arises. If a plurality of small fans is provided, although the space for each of the fans is reduced, a large space is necessary for those fans when it is considered as a whole. Consequently, the size and thickness of the electronic apparatus may not be reduced.

Japanese Registered Utility Model No. 3082472 is an example of prior art, the prior art discloses that an electronic apparatus is cooled from outside by externally attaching a device including a fan to the apparatus and feeding air to the apparatus. Japanese Unexamined Patent Application Publication No. 11-53063 is an example of prior art, the prior art discloses that an electronic apparatus includes a casing having a ventilation opening, through which air is fed into the apparatus from an external device including a fan.

In these prior art references, a cooling function for the electronic apparatuses take effect when the devices including the fans are externally attached to the electronic apparatuses. That is, with the electronic apparatuses alone, the cooling functions with the fans do not work. In a case where a device including a fan and having a function of cooling with the fan has any other functions as well, an electronic apparatus needs to be used with the device externally attached thereto even if the other functions are not necessary, that is, even if the device is used only for the purpose of cooling.

### SUMMARY

According to an aspect of an embodiment, an electronic apparatus includes a main unit having a front face and a rear face and housing an electronic component; a support base; and a post provided upright on the support base and connected to the rear face of the main unit while supporting the main unit in such an orientation that the front face of the main unit extends upright, the post including a fan producing a flow of air passing through an inside of the main unit.

The object and advantages of the various embodiments will be realized and attained by at least the features, elements, and combinations particularly pointed out in the claims. It is to be understood that both the foregoing general description and the following detailed description are exemplary and explanatory and are not restrictive of the various embodiments, as claimed.

Additional aspects and/or advantages will be set forth in part in the description which follows and, in part, will be apparent from the description, or may be learned by practice of the various embodiments.

### BRIEF DESCRIPTION OF THE DRAWINGS

FIG. 1 is a perspective view of an electronic apparatus according to an embodiment;

FIG. 2 illustrates an electronic apparatus according to a comparative example seen from the rear thereof;

FIGS. 3A and 3B are perspective views of a duct member and a fan;

FIG. 4 is an exploded perspective view in which a main unit and the duct member are separated;

FIG. 5 is another exploded perspective view in which the main unit with the duct member being attached thereto and the fan are separated;

FIG. 6 illustrates the relationship between a fitting part on the rear face of the main unit and a post in the electronic apparatus;

FIG. 7 is a side view of the electronic apparatus; and

FIGS. 8A and 8B are cross-sectional views of the electronic apparatus seen from one side and each illustrates the airflow produced when the fan is rotated.

### DETAILED DESCRIPTION OF THE EMBODIMENTS

An embodiment of the present application will now be described.

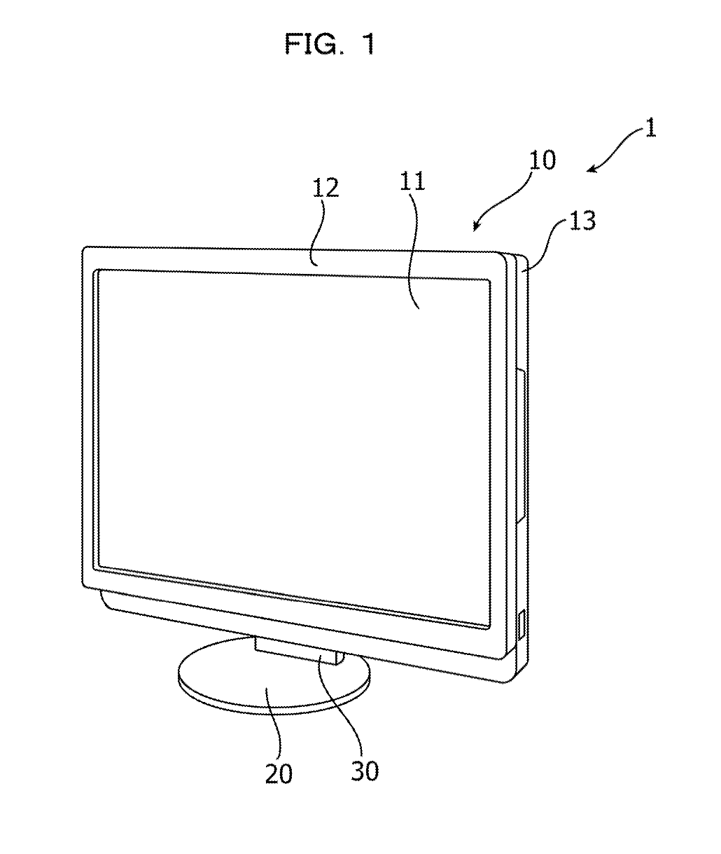

FIG. 1 is a perspective view of an electronic apparatus 1 according to an embodiment.

The electronic apparatus 1 includes a main unit 10, a support base 20, and a post 30. The electronic apparatus 1 has, for example, a function as a personal computer and/or a function as a television receiver.

The main unit 10 has a display screen 11 on the front face thereof. The display screen 11 displays an image in accordance with an image signal. The main unit 10 is provided thereinside with various electronic components such as those for realizing an arithmetic function of the personal computer. Some of the electronic components generate heat when in operation and need to be forcibly cooled with airflow produced by a fan.

The main unit 10 has on the front face thereof a frame-like front cover 12 surrounding the display screen 11, and on the rear face thereof a rear cover 13.

The support base 20 may be placed such that the bottom face thereof is in contact with a level member such as a floor or a desk top, for example.

The post 30 is provided upright on the support base 20 and is connected to the rear face of the main unit 10. The post 30 supports the main unit 10 such that the main unit 10 is oriented with the front face thereof extending upright and such that the angle of elevation of the front face of the main unit 10 is changeable, for example. The post 30 also supports the main unit 10 such that the orientation of the main unit 10 that has been changed by a user, for example, is maintained. The support base 20 and the post 30 together form a supporting component that support the main unit 10. The support base 20 and the post 30 may either be manufactured separately and then be assembled together or be manufactured as an integral body.

A comparative example to the embodiment will now be described.

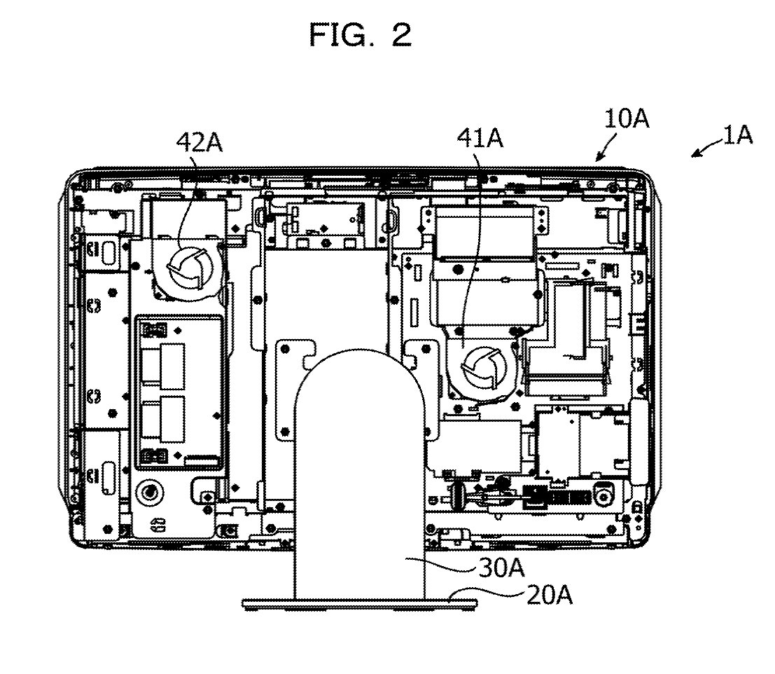

FIG. 2 illustrates an electronic apparatus 1A according to a comparative example seen from the rear thereof.

In FIG. 2, elements of the comparative example are denoted by adding a suffix “A” to each of reference numerals for corresponding elements of the embodiment illustrated in FIG. 1 and others. FIG. 2 illustrates the inside of a main unit 10A with a rear cover of the main unit 10A (see the rear cover 13 illustrated in FIG. 1) being removed.

The electronic apparatus 1A according to the comparative example illustrated in FIG. 2 includes the main unit 10A, a support base 20A, and a post 30A, as does the electronic apparatus 1 according to the embodiment (see FIG. 1).

What is to be focused on in comparing the comparative example and the embodiment is that, in the electronic apparatus 1A according to the comparative example, two fans 41A and 42A are provided in the main unit 10A. In the electronic apparatus 1A according to the comparative example, the fans 41A and 42A of relatively small sizes are provided at different positions in the main unit 10A, as a matter of the layout of components provided in the main unit 10A. Since the electronic apparatus 1A includes a large display screen (such as the display screen 11 illustrated in FIG. 1, for example), the vertical and horizontal dimensions of the main unit 10A are inevitably large in accordance with the vertical and horizontal dimensions of the display screen.

Description of the embodiment will now be resumed.

The electronic apparatus 1 according to the embodiment has a fan 40 inside the post 30, not inside the main unit 10.

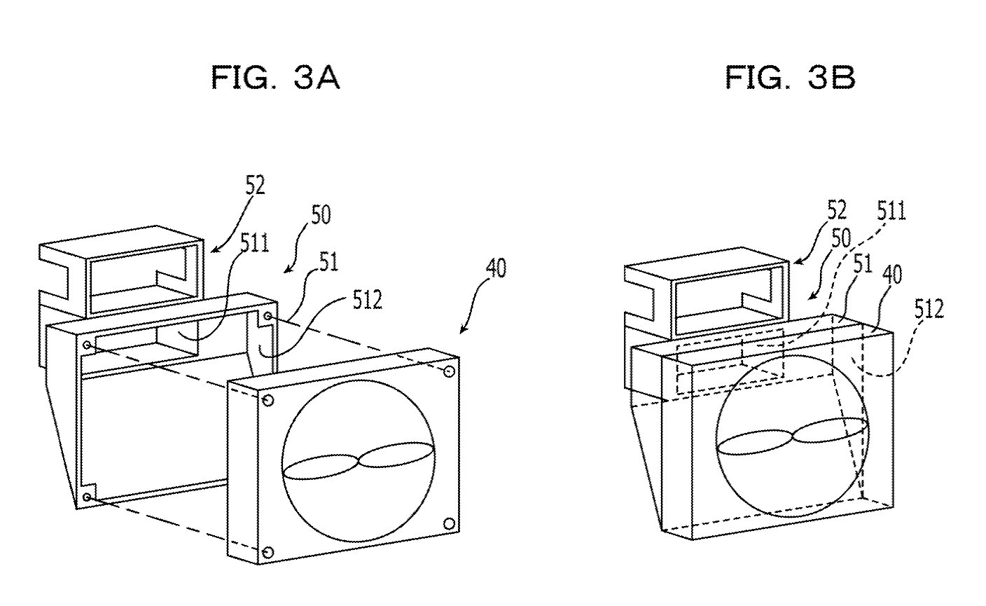

FIGS. 3A and 3B are perspective views of a duct member 50 and the fan 40. FIG. 3A is an exploded perspective view in which the fan 40 is separated from the duct member 50. FIG. 3B is a perspective view in which the fan 40 is attached to the duct member 50.

The duct member 50 includes a duct portion 51 and a tilt-cover portion 52. The duct portion 51 includes a communication-path portion 511 and a fan-receiving portion 512. The communication-path portion 511 allows the inside of the main unit 10 and the inside of the post 30 to communicate with each other. The fan-receiving portion 512 receives the fan 40 attached thereto. The duct member 50 has a hollow, e.g., an airflow path, extending through the communication-path portion 511 and the fan-receiving portion 512.

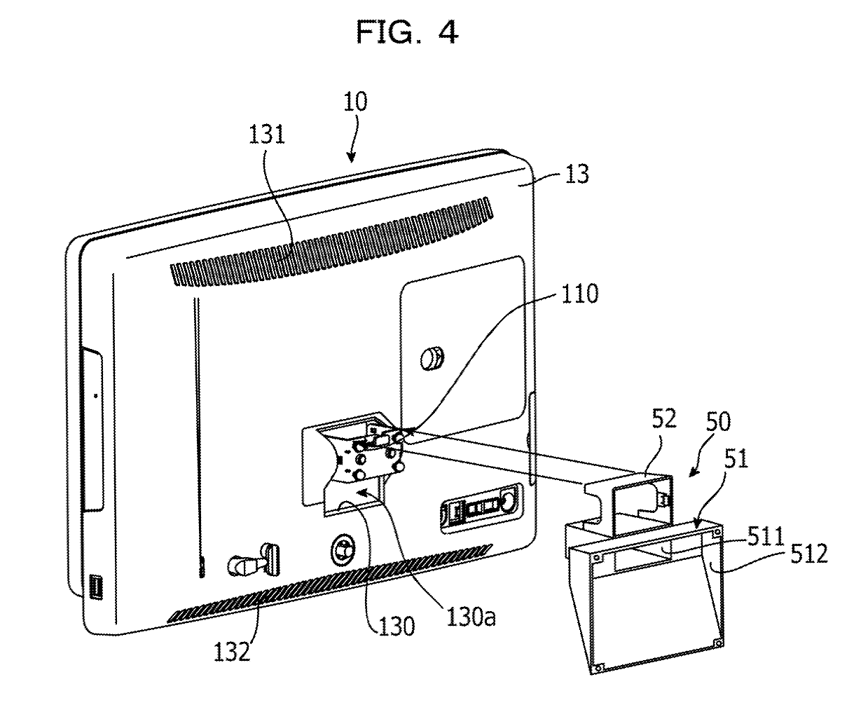

The tilt-cover portion 52 is a cover provided over a metal fitting 110 (see FIG. 4) forming a connector. The connector connects the post 30 and the main unit 10 to each other. The connector includes a tilting mechanism allowing the angle of elevation of the main unit 10 to be changeable. Therefore, in the embodiment, the cover is named tilt-cover portion 52.

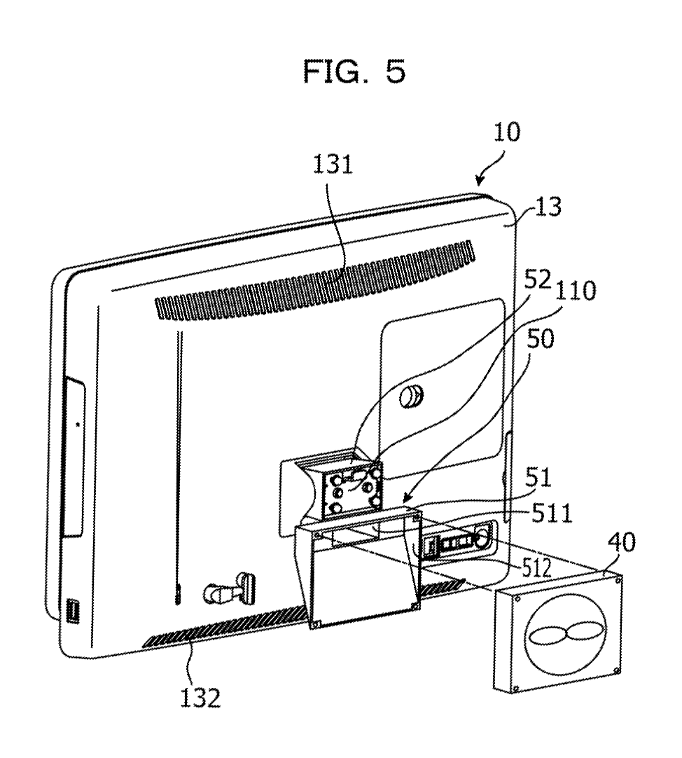

FIG. 4 is an exploded perspective view in which the main unit 10 and the duct member 50 are separated. FIG. 5 is another exploded perspective view in which the main unit 10 with the duct member 50 being attached thereto and the fan 40 are separated. FIGS. 4 and 5 illustrate the main unit 10 seen from the rear.

The rear cover 13 of the main unit 10 has on the upper and lower sides thereof ventilation openings 131 and 132, respectively, connected to the inside of the main unit 10.

The rear cover 13 has an opening 130. The metal fitting 110 provided in the main unit 10 projects from the opening 130, specifically, from the upper side of the opening 130. The lower side of the opening 130 provides an airhole 130a. The airhole 130a is an example of the main-side communication opening according to the present application. The metal fitting 110 employs the tilting mechanism allowing the angle of elevation of the front face of the main unit 10 to be changeable and is fitted to the post 30 (see FIG. 1). The opening 130 is an example of the first opening of the main unit.

The duct member 50 is attached to the main unit 10 such that the tilt-cover portion 52 thereof covers the metal fitting 110 and the communication-path portion 511 thereof is fitted into the airhole 130a. The fan 40 is attached to the fan-receiving portion 512 of the duct member 50.

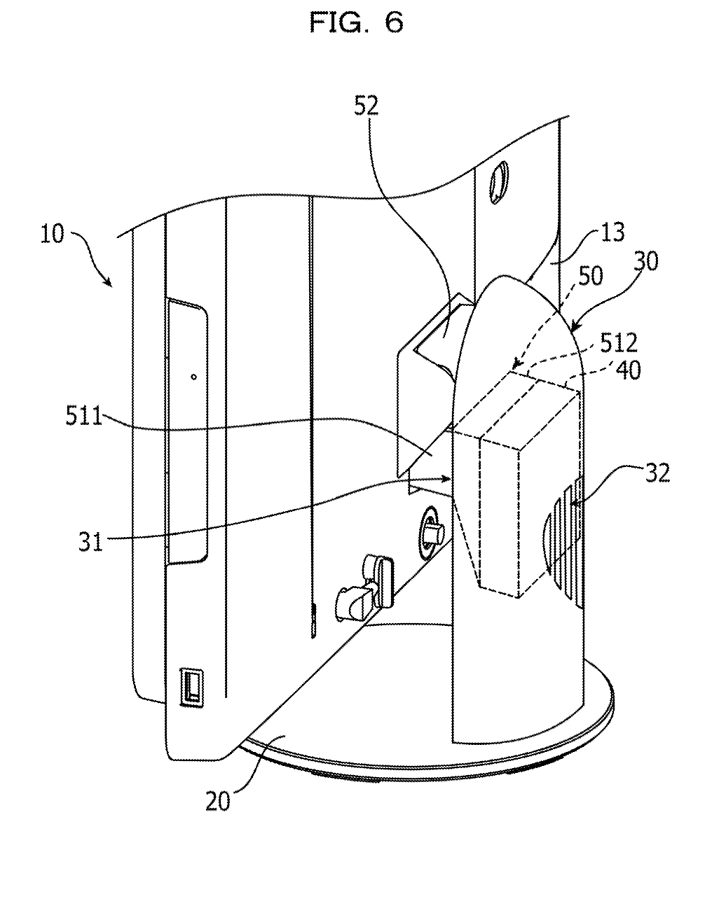

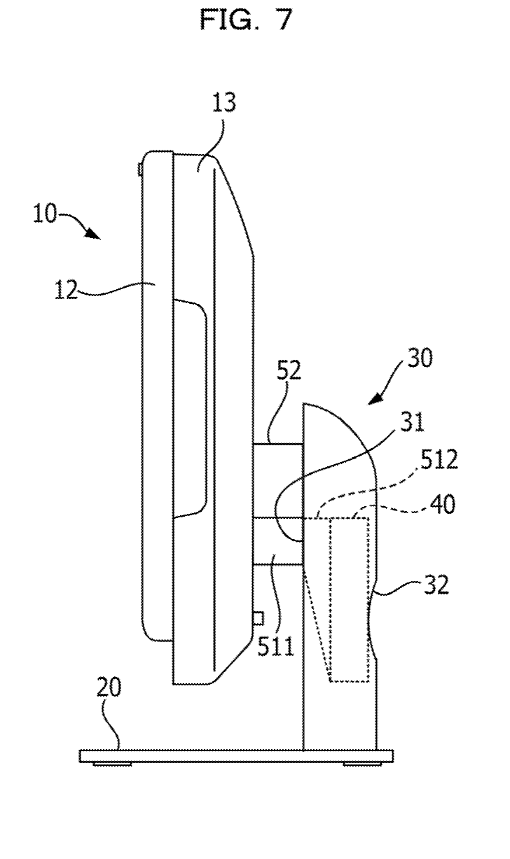

FIG. 6 illustrates the relationship between a fitting part on the rear face of the main unit 10 and the post 30 in the electronic apparatus 1. FIG. 7 is a side view of the electronic apparatus 1. FIG. 7 illustrates the positions of the duct member 50 and the fan 40.

The post 30 has on a side thereof near the main unit 10 a communication opening 31 that allows the communication-path portion 511 of the duct member 50 to project therefrom. The communication opening 31 is provided at a position facing the airhole 130a. Air flows in and out between the communication opening 31 and the airhole 130a. The post 30 also has a ventilation opening 32 on the rear thereof. The fan-receiving portion 512 of the duct member 50 and the fan 40 attached thereto are positioned inside the post 30 in such a manner as to face the ventilation opening 32.

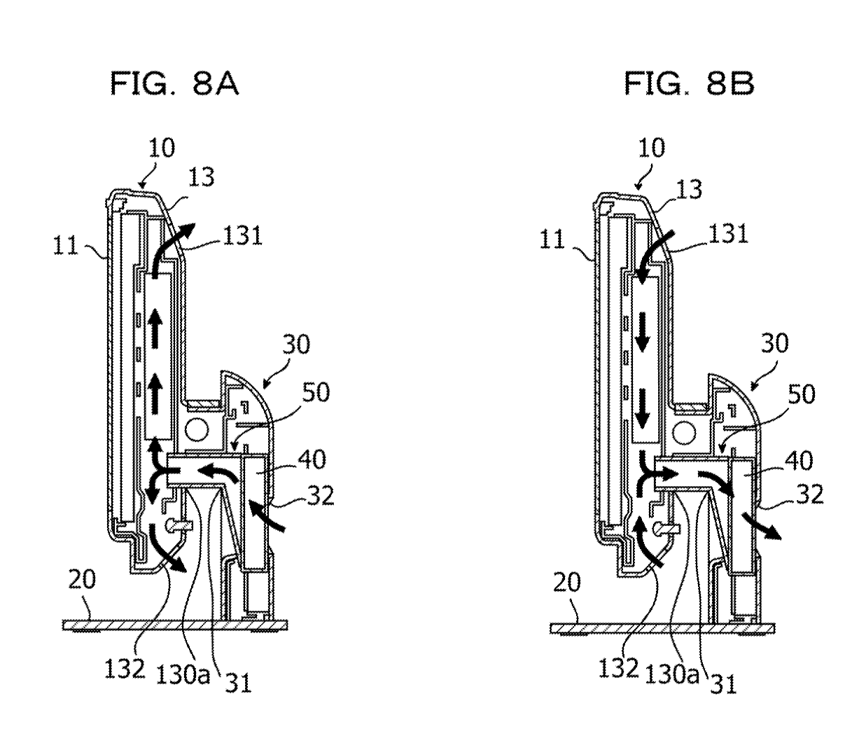

FIGS. 8A and 8B are cross-sectional views of the electronic apparatus 1 seen from one side and each illustrates the airflow produced when the fan 40 is rotated.

FIG. 8A illustrates the airflow when the fan 40 is an intake fan.

When the fan 40 is rotated, air is taken in from the ventilation opening 32 of the post 30 and is fed through the fan 40 into the duct member 50. The air passes through the airflow path provided in the duct member 50, the communication opening 31 of the post 30, and the airhole 130a of the main unit 10, and flows into the main unit 10. The air taken into the main unit 10 further advances through the main unit 10 while absorbing heat from the electronic components provided in the main unit 10. The air advancing upward in the main unit 10 is exhausted to the outside of the main unit 10 from the ventilation opening 131. The air advancing downward in the main unit 10 is exhausted to the outside of the main unit 10 from the ventilation opening 132.

FIG. 8B illustrates the airflow when the fan 40 is an exhaust fan.

When the fan 40, an exhaust fan in this case, is rotated, air is taken in from the ventilation openings 131 and 132 provided on the upper and lower sides of the main unit 10 and flows through the main unit 10. The air taken into the main unit 10 is heated with heat from the electronic components in the main unit 10 while flowing through the main unit 10. The heated air passes through the airflow path provided in the duct member 50, flows into the post 30, passes through the fan 40, and is exhausted to the outside from the ventilation opening 32.

In the electronic apparatus 1 according to the embodiment, the fan 40 that produces airflow for cooling the inside of the main unit 10 is provided inside the post 30. Therefore, the thickness and weight of the main unit 10 are correspondingly reduced. Since the post 30 is one of the components of the electronic apparatus 1, there is no need to provide an external device for the cooling purpose. Moreover, it is more convenient to provide a large space in the post 30 than in the main unit 10. Therefore, the fan 40 provided in the post 30 may be relatively large. Particularly, when the main unit 10 has a large display screen, the post 30 may also be large so that the main unit 10 is supported stably. Such a large post 30 provides a space sufficient for housing the fan 40. Therefore, a necessary volume of airflow may be produced without rotating the fan 40 at an excessively high speed. Accordingly, the noise generated by the rotation of the fan 40 may be reduced, and the life of the fan 40 may be extended.

In the electronic apparatus 1 according to the embodiment, only a single fan 40 housed in the post 30 is provided. If a larger volume of airflow needs to be produced, the electronic apparatus 1 including the fan 40 provided in the post 30 may also include an auxiliary fan provided in the main unit 10. Even in such a case, the thickness and weight of the main unit 10 and the noise of rotation of the fans may be reduced and the useful lives of the fans may be extended more than in the case where all of the fans for producing a necessary volume of airflow are provided in the main unit as in the comparative example illustrated in FIG. 2.

In the embodiment, the airhole 130a of the main unit 10 and the communication opening 31 of the post 30 are positioned so as to face each other. The airhole 130a and the communication opening 31, however, may not necessarily face each other, as long as they communicate with each other allowing air to flow in and out therebetween through the duct member 50 whose shape is appropriately modified.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An electronic apparatus comprising:
a main unit having a front face and a rear face and housing an electronic component;
a support base; and
a post provided upright on the support base and connected to the rear face of the main unit while supporting the main unit in such an orientation that the front face of the main unit extends upright, the post including a fan producing a flow of air passing through an inside of the main unit.

2. The electronic apparatus according to claim 1,
wherein the main unit and the post include a main-side communication opening and a post-side communication opening, respectively, between which air flows in and out,
wherein the main unit has a main-side ventilation opening connected to the main-side communication opening through the inside of the main unit,
wherein the post has a post-side ventilation opening connected to the post-side communication opening through an inside of the post, and
wherein the fan is provided inside the post and produces a flow of air passing through the post-side ventilation opening and the main-side ventilation opening.

3. The electronic apparatus according to claim 1, further comprising:
a duct member including a connecting portion connecting the main-side communication opening and the post-side communication opening to each other, and a fan-receiving portion positioned on an inside of the post, the duct member providing an airflow path extending through the connecting portion and the fan-receiving portion,
wherein the fan is attached to the fan-receiving portion.

4. The electronic apparatus according to claim 1, wherein the main unit has on the front face thereof a display screen that displays an image in accordance with an image signal.

5. The electronic apparatus according to claim 1, wherein the post supports the main unit at the rear face of the main unit such that an angle of elevation of the front face of the main unit is changeable.

6. An electronic apparatus comprising:
a main unit housing an electronic component;
a support base; and
a post provided upright on the support base and connected to a portion of the main unit while supporting the main unit such that an orientation of the main unit is maintained, the orientation being changeable, the post including a fan producing a flow of air passing through an inside of the main unit.

7. A supporting component comprising:
a connector connected to a portion of a main unit that houses an electronic component and maintaining an orientation of the main unit, the orientation being changeable;
a cover covering a first opening of the main unit and the connector and including a second opening, the cover providing an airflow path between the first opening and the second opening; and
a fan housed in the cover and producing a flow of air in the airflow path between the first opening and the second opening.
